(19) United States
(12) Patent Application Publication
(10) Pub. No.: US 2015/0054537 A1
(43) Pub. Date: Feb. 26, 2015

(54) SYSTEM AND METHOD FOR ASSEMBLING A PROBE HEAD

(71) Applicant: Corad Technology Inc., Santa Clara, CA (US)

(72) Inventor: Frederick L. Taber, JR., LaGrangeville, NY (US)

(73) Assignee: Corad Technology Inc., Santa Clara, CA (US)

(21) Appl. No.: 13/973,748

(22) Filed: Aug. 22, 2013

(51) Int. Cl. G01R 1/073

(52) U.S. Cl. CPC G01R 1/07364
USPC 324/750.25

(57) ABSTRACT

A method of assembling a probe head for a probe card interface is disclosed. The probe head includes a plurality of alignment plates, wherein each of the alignment plates includes a set of holes. The plurality of alignment plates are stacked so that each of the alignment plates is adjacent to at least one other alignment plate and a set of holes in each of the alignment plates is aligned with a corresponding set of holes in each of the remaining alignment plates. A set of probe wires is then inserted through the set of holes, respectively, in each of the plurality of alignment plates. After the set of probe wires are inserted, the plurality of alignment plates are spaced so that none of the plurality of alignment plates is adjacent to another alignment plate. One or more multi-piece spacers may be used to space the alignment plates.

### TECHNICAL FIELD

The present invention relates generally to probe cards used to test integrated circuit devices and specifically to probe head assemblies for probe cards.

### BACKGROUND OF RELATED ART

Probe cards are typically used in the testing of integrated circuit (IC) devices. Due to their design, probe cards are particularly advantageous for testing entire semiconductor wafers to detect any manufacturing defects before they are diced and packaged. For example, a probe card is typically formed from a printed circuit board (PCB) having a number of electrical contact elements and/or traces disposed thereon to connect to a testing apparatus. The PCB is connected to a probe head having a number of pins that are brought into contact with a device under test (DUT) to facilitate the transmission of electrical signals to and from the DUT. Accordingly, the probe card acts as an interface between the testing apparatus and the DUT.

FIG. 1A shows a cross-sectional view of a typical probe head 100. The probe head 100 includes a number of alignment plates 110-130 that are used to align and/or interface a set of probe wires 150 with a DUT. More specifically, each of the alignment plates 110-130 includes a set of holes 112-132, respectively, through which a corresponding probe wire 150 is inserted. In this manner, the alignment plates 110-130 may be used to guide the probe wires 150 into contact with corresponding electrical contacts (e.g., pads and/or bumps) of the DUT.

The probe head 100 also includes a set of spacers 140(1)-140(2) that are provided between the alignment plates 110-130 to allow the probe wires 150 to bend or flex when making contact with the DUT. As shown in FIG. 1B, each spacer 140 is formed from a layer of insulating material 141 (e.g., ceramic) with a hollow center 143, through which the probe wires 150 are passed, to allow the probe wires 150 to bend freely. For example, the electrical contacts of the DUT are typically very small and delicate. Thus, by allowing the probe wires 150 to bend, the spacers 140(1)-140(2) may ensure that the probe wires 150 make contact with one or more of the electrical contacts (i.e., with sufficient force) without damaging them.

Furthermore, the pitch (i.e., spacing between the probe wires 150) of the probe head is typically very small in order to properly align with corresponding contact pads of the DUT. Thus, the middle (or “floating”) alignment plate 130 helps to maintain separation between the probe wires 150. In other words, the floating alignment plate 130 prevents the probe wires 150 from coming into contact with one another when they bend or flex.

The alignment plates 110-130 and spacers 140(1)-140(2) are typically assembled first (e.g., as shown in FIG. 1A), before the probe wires 150 are inserted. However, due to the gap between the alignment plates 110-130 (created by the spacers 140(1) and 140(2)), the probe wires 150 must be carefully threaded through the holes 112-132 of the corresponding alignment plates 110-130. Therefore, individual probe wires 150 are typically inserted by hand (i.e., manually).

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

A method and apparatus for assembling a probe head is disclosed. The probe head includes a number of alignment plates, each of the alignment plates including a set of holes. In the present embodiments, the alignment plates are stacked so that each alignment plate is directly adjacent to at least one other alignment plate and a set of holes in each of the alignment plates is aligned with a correspond set of holes in each of the remaining alignment plates. A set of probe wires is then inserted through the set of holes, respectively, in each of the plurality of alignment plates. After the probe wires are inserted, the alignment plates are spaced so that none of the alignment plates is directly adjacent to another alignment plate.

For some embodiments, one or more multi-piece spacers may be used to space apart the alignment plates. Each multi-piece spacer may be assembled from at least two parts, and enables the set of probe wires to bend or flex when making contact with a device under test.

For some embodiments, the alignment plates may include at least an upper alignment plate and a lower alignment plate. Furthermore, a floating alignment plate may be provided between the upper and lower alignment plates to control a bending or flexing of the probe wires. More specifically, the floating alignment plate may enable the probe wires to bend or flex without making contact with one another.

Accordingly, the probe head assembly techniques described herein with respect to the exemplary embodiments may provide an automated (e.g., computer-controlled) process for threading a probe head (i.e., inserting probe wires through the alignment plates of the probe head). In addition, at least some of the present embodiments may allow for the entire probe head assembly process to be performed more efficiently.

### BRIEF DESCRIPTION OF THE DRAWINGS

The present embodiments are illustrated by way of example and not intended to be limited by the figures of the accompanying drawings, where:

FIGS. 1A-1B show cross-sectional and planar views of a typical probe head and a spacer component of the probe head, respectively;

FIG. 2 is an illustrative flowchart depicting an exemplary operation for assembling a probe head in accordance with present embodiments;

FIGS. 3A-3C are cross-sectional views depicting a probe head assembly process in accordance with present embodiments;

FIGS. 4A-4B show planar views of the multi-piece spacer depicted in FIG. 3C; and

FIG. 5 is a block diagram of a controller for a probe assembly tooling in accordance with some embodiments.

### DETAILED DESCRIPTION

In the following description, numerous specific details are set forth to provide a thorough understanding of the present disclosure. Also, in the following description and for purposes of explanation, specific nomenclature is set forth to provide a thorough understanding of the present embodiments. However, it will be apparent to one skilled in the art that these specific details may not be required to practice the present embodiments. In other instances, well-known circuits and devices are shown in block diagram form to avoid obscuring the present disclosure. The term “coupled” as used herein means connected directly to or connected through one or more intervening components or circuits. Any of the signals provided over various buses described herein may be time-multiplexed with other signals and provided over one or more common buses. Additionally, the interconnection between circuit elements or software blocks may be shown as buses or as single signal lines. Each of the buses may alternatively be a single signal line, and each of the single signal lines may alternatively be buses, and a single line or bus might represent any one or more of a myriad of physical or logical mechanisms for communication between components.

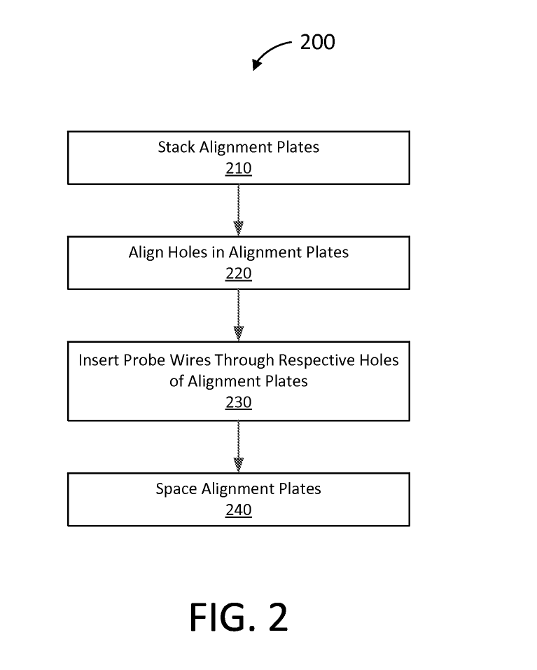

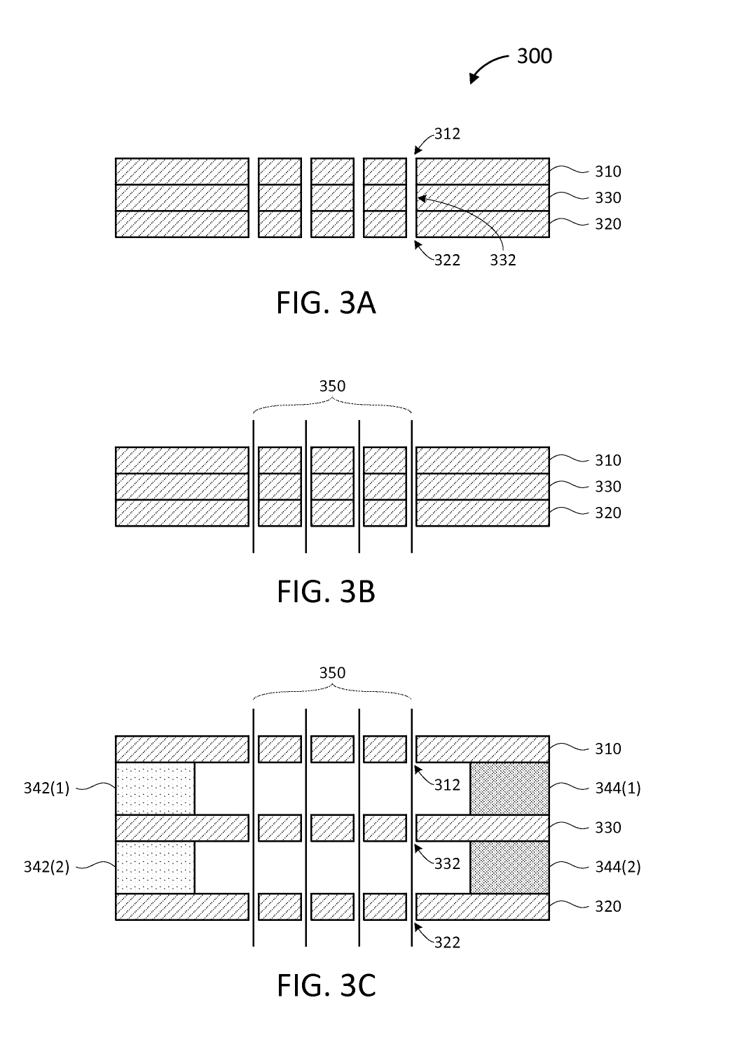

FIG. 2 is an illustrative flowchart depicting an exemplary operation 200 for assembling a probe head in accordance with present embodiments. For illustrative purposes, the operation 200 is herein described with reference to FIGS. 3A-3C, which show cross-sectional views of a probe head 300. The probe head 300 includes an upper alignment plate 310, a lower alignment plate 320, and a floating alignment plate 330 that may be used to align and/or interface a set of probe wires 350 with a device under test (DUT). For some embodiments, the alignment plates 310-330 are made from an insulating (e.g., ceramic) material. Each of the alignment plates 310-330 includes a set of holes 312-332, respectively, through which a corresponding probe wire 350 may be inserted.

With reference to FIG. 3A, the alignment plates 310-330 are first stacked on top of one another (210). For some embodiments, the alignment plates 310-330 may be stacked so that each of the alignment plates 310-330 is directly adjacent to another alignment plate. For example, the floating alignment plate 330 may be stacked on top of the lower alignment plate 320, and the upper alignment plate 310 may be stacked on top of the floating alignment plate 330. Furthermore, the alignment plates 310-330 may be aligned such that the holes 312-332 of the respective alignment plates 310-330 coincide with one another (220). For some embodiments, each hole of an alignment plate (e.g., alignment plate 310) may be aligned with corresponding holes of the other alignment plates (e.g., alignment plates 320-330).

With reference to FIG. 3B, probe wires 350 may then be inserted through respective holes of the alignment plates 310-330 (230). For some embodiments, the probe wires 350 may be inserted using a machine and/or computer-controlled apparatus. For example, because the alignment plates 310-330 are stacked adjacent to one another, corresponding holes 312-332 in each alignment plate effectively form a continuous channel from the top of the upper alignment plate 310 through to the bottom of the lower alignment plate 320. More specifically, the holes 312 of the upper alignment plate 310 may guide the insertion of the probe wires 350 through to corresponding holes 332 of the floating alignment plate 330 (and vice-versa). Similarly, the holes 332 of the floating alignment plate 330 may further guide the insertion of the probe wires 350 through to corresponding holes 322 of the lower alignment plate 320 (and vice-versa). During assembly, a flat surface may be provided below alignment plate 320 to stop the wires from falling completely through the holes. In this manner, all three of the alignment plates 310-330 may be threaded in a quicker and more efficient manner (e.g., requiring less precision in placement and/or alignment of the wires) compared to prior art threading techniques.

With reference to FIG. 3C, after the probe wires 350 are inserted through the holes 312-332, the alignment plates 310-330 may then be spaced apart or separated (240). For some embodiments, the probe wires 350 may be spaced by inserting a multi-piece spacer (e.g., assembled from spacer components 342 and 344) between adjacent alignment plates 310-330. For example, a first set of spacers components 342(1) and 344(1) may be provided between the upper alignment plate 310 and the floating alignment plate 330. Furthermore, a second set of spacer components 342(2) and 344(2) may be provided between the lower alignment plate 320 and the floating alignment plate 330. The multi-piece spacers create a separation between the alignment plates 310-330 to provide the probe wires 350 room to bend or flex when force is applied to either end (e.g., when the probe wires 350 make contact with the electrical contacts of a DUT). The resulting spacing between alignment plates may be established by the thickness of the spacers 342(1)/344(1) and 342(2)/344(2). For some embodiments, spacers 342(1)/344(1) may differ in thickness from spacers 342(2)/344(2).

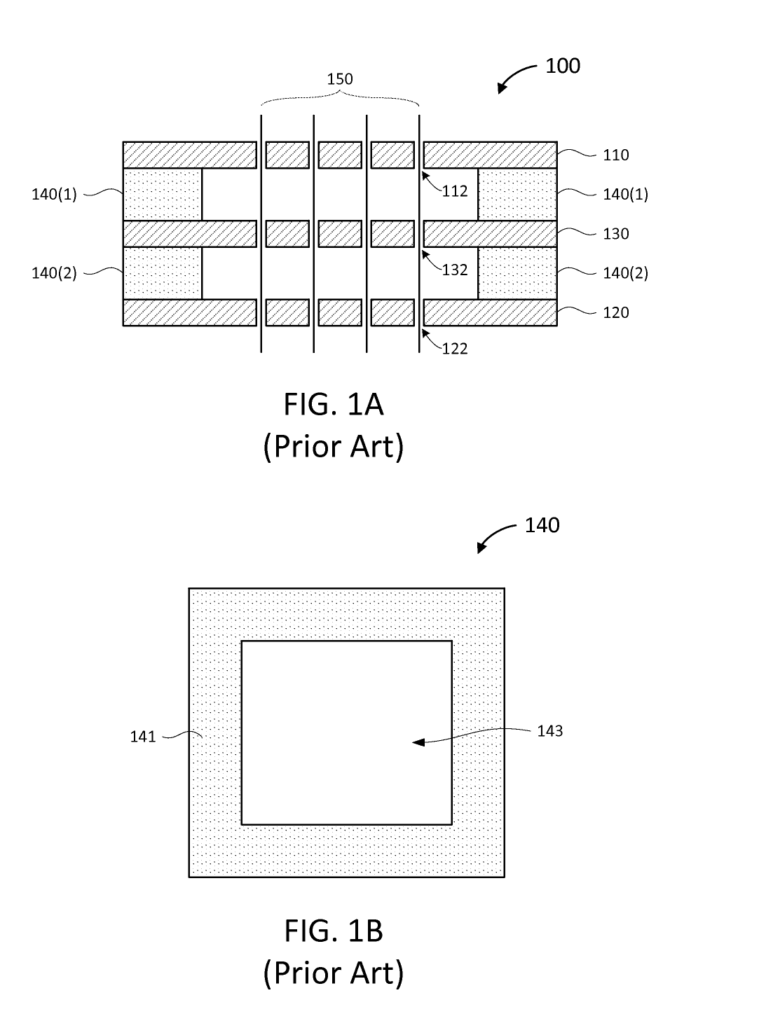

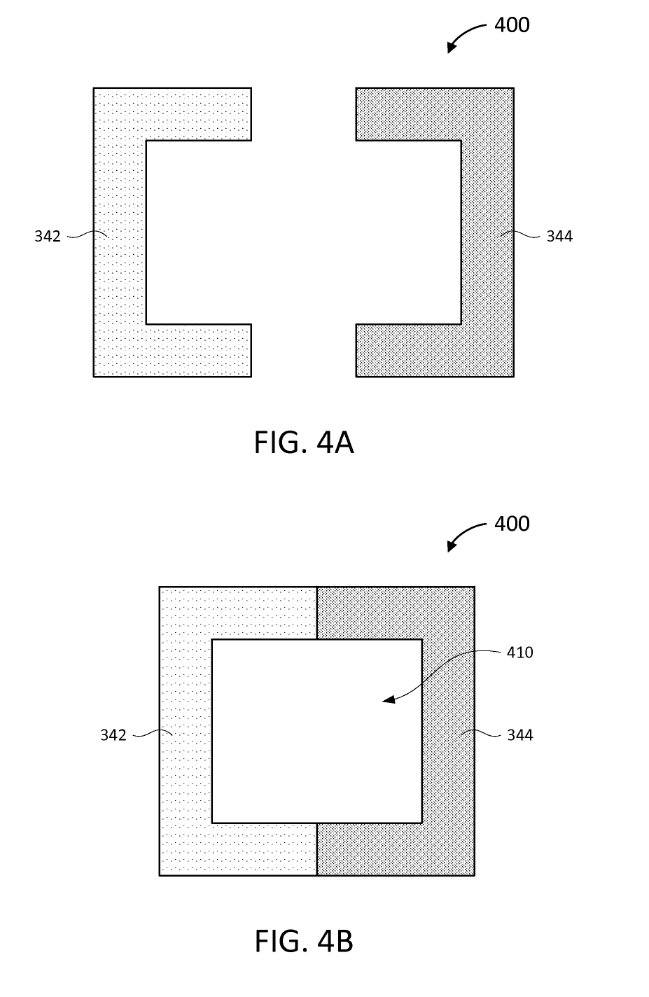

FIGS. 4A-4B show more detailed embodiments of the multi-piece spacer shown in FIG. 3C. As described above, the multi-piece spacer 400 includes two spacer components 342 and 344. For some embodiments, each of the spacer components 342 and 344 may be formed from an insulating (e.g., ceramic) material. It should be noted, however, that both of the spacer components may be formed from the same material. As shown in FIG. 4A, each spacer component 342 and 344 is a separable component that may be combined with another spacer component (e.g., spacer component 342 or 344) to form an assembled multi-piece spacer. For some embodiments, spacer component 342 may be identical to spacer component 344. As shown in FIG. 4B, the multi-piece spacer 400, once assembled, may resemble the spacer 100 shown in FIG. 1. For example, the spacer components 342 and 344 may form a ring-like structure having a hollow center 410 that is provided for the probe wires 350 to pass through (e.g., with sufficient lateral space to bend or deflect). It should be noted that, for other embodiments, the multi-piece spacer 400 may be formed from any number of spacer components.

As shown in FIGS. 4A-4B, the multi-piece spacer 400 can be assembled by simply bringing two or more spacer components (e.g., spacer components 342 and 344) into alignment (note that the spacer components may or may not touch). This feature enables the multi-piece spacer 400 to be inserted into the probe head 300 at any time during the assembly process, even after the probe wires 350 have been inserted through the alignment plates 310-330. Thus, for some embodiments, a portion or all of the probe head assembly process 200 may be performed by an automated (e.g., computer-controlled) device or system. This provides an automated (e.g., computer-controlled) process for threading a probe head (i.e., inserting probe wires through the alignment plates of the probe head). This, in turn, may provide a quicker and more robust probe head assembly process in comparison to prior art techniques.

It should be noted that, while the probe head 300 includes three alignment plates 310-330, the probe assembly operation 200 described above may be easily applied to probe heads having of fewer or more alignment plates. Thus, for some embodiments, the probe head 300 may include only the upper alignment plate 310 and lower alignment plate 320 (i.e., without the floating alignment plate 330). For other embodiments, the probe head 300 may include multiple floating alignment plates 330.

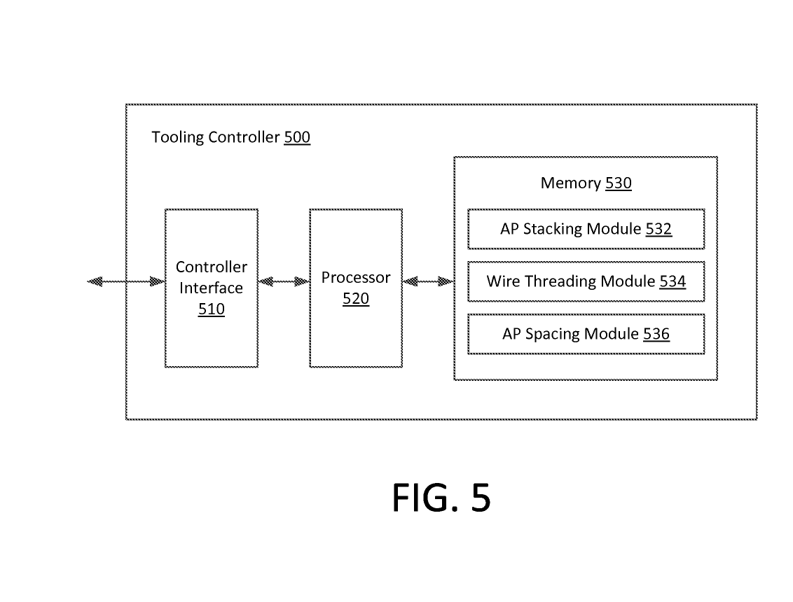

FIG. 5 is a block diagram of a controller 500 for a probe assembly tooling in accordance with some embodiments. The tooling controller 500 includes a controller interface 510, a processor 520, and memory 530. The controller interface 510 may be used for communicating instructions to and/or from the controller 500. For example, the controller interface 510 may output instructions from the processor 520 to other components of the probe assembly tooling to carry out one or more steps of the probe head assembly operation. It should be noted that the probe assembly tooling may be a machine or device comprised of one or more computer-controllable mechanical components (e.g., robotic arms) that are well known in the art.

Memory 530 may include a non-transitory computer-readable storage medium (e.g., one or more nonvolatile memory elements, such as EPROM, EEPROM, Flash memory, a hard drive, etc.) that can store the following software modules:
an alignment plate (AP) stacking module 532 to stack and align a set of alignment plates of the probe head;
a wire threading module 534 to insert a set of probe wires through corresponding holes in each of the alignment plates; and
an AP spacing module 536 to space the alignment plates after the probe wires are inserted. Each software module may include instructions that, when executed by the processor 520, may cause the probe assembly tooling (or component thereof) to perform the corresponding function. Thus, the non-transitory computer-readable storage medium of memory 530 may include instructions for performing all or a portion of the operations described with respect to FIG. 2.

The processor 520, which is coupled between the controller interface 510 and memory 530, may be any suitable processor capable of executing scripts of instructions of one or more software programs stored in the tooling controller 500 (e.g., within memory 530). For example, the processor 520 may execute the AP stacking module 522, the wire threading module 524, and/or the AP spacing module 526.

The AP stacking module 532 may be executed by the processor 520 to cause the probe assembly tooling to stack and align a set of alignment plates of the probe head. For example, the alignment plates may be stacked so that each alignment plate is directly adjacent to another alignment plate. Furthermore, a set of holes in each of the alignment plates may be aligned with a corresponding set of holes in each of the other alignment plates. For some embodiments, the set of alignment plates may include an upper alignment plate, a lower alignment plate, and a floating alignment plate.

The wire threading module 534 may be executed by the processor 520 to cause the probe assembly tooling to insert a set of probe wires through corresponding holes in each of the alignment plates. For example, while the alignment plates are stacked adjacent to one another, corresponding holes in each alignment plate effectively may form a continuous channel from the top of the upper alignment plate through to the bottom of the lower alignment plate. Accordingly, the holes of the upper alignment plate may guide the insertion of the probe wires through to corresponding holes of the floating alignment plate which, in turn, guide the insertion of the probe wires through the holes of the lower alignment plate.

The AP spacing module 526 may be executed by the processor 520 to space the alignment plates after the probe wires are inserted. For some embodiments, the processor 520, in executing the AP spacing module 526, may cause the probe assembly tooling to space the alignment plates by inserting multi-piece spacers (e.g., as described above with respect to FIGS. 4A-4B) between adjacent alignment plates. Accordingly, the multi-piece spacers may create a separation between the alignment plates to allow the probe wires to bend or flex when making contact with a DUT.

In the foregoing specification, the present embodiments have been described with reference to specific exemplary embodiments thereof. It will, however, be evident that various modifications and changes may be made thereto without departing from the broader scope of the disclosure as set forth in the appended claims. The specification and drawings are, accordingly, to be regarded in an illustrative sense rather than a restrictive sense. For example, the method steps depicted in the flow chart of FIG. 2 may be performed in other suitable orders, multiple steps may be combined into a single step, and/or some steps may be omitted.

What is claimed is:

1. A method of assembling a probe head for a probe card interface, the method comprising:
stacking a plurality of alignment plates so that each of the plurality of alignment plates is adjacent to at least one other alignment plate and a set of holes in each of the plurality of alignment plates is aligned with a corresponding set of holes in each of the remaining alignment plates;
inserting a set of probe wires through the set of holes, respectively, in each of the plurality of alignment plates; and
spacing the plurality of alignment plates, after the set of probe wires are inserted, so that none of the plurality of alignment plates is adjacent to another alignment plate.

2. The method of claim 1, wherein the plurality of alignment plates includes at least an upper alignment plate and a lower alignment plate.

3. The method of claim 2, wherein the plurality of alignment plates further includes:
a floating alignment plate, provided between the upper and lower alignment plates, to control a bending or flexing of the probe wires.

4. The method of claim 3, wherein the floating alignment plate enables the probe wires to bend or flex without contacting one another.

5. The method of claim 1, wherein spacing the plurality of alignment plates comprises:
inserting one or more spacers between the plurality of alignment plates.

6. The method of claim 5, wherein the one or more spacers enable the set of probe wires to bend or flex when making contact with a device under test.

7. The method of claim 5, wherein each of the one or more spacers comprises a multi-piece spacer that is assembled from at least two parts.

8. A computer-readable storage medium containing program instructions that, when executed by a processor provided within a probe assembly tooling, causes the tooling to:
insert a set of probe wires through a set of holes, respectively, in each of a plurality of alignment plates;
wherein, prior to the set of probe wires being inserted, the plurality of alignment plates are stacked so that each of the plurality of alignment plates is adjacent to at least one other alignment plate and a set of holes in each of the plurality of alignment plates is aligned with a corresponding set of holes in each of the remaining alignment plates; and
wherein, after the set of probe wires are inserted, the plurality of alignment plates are spaced so that none of the plurality of alignment plates is adjacent to another alignment plate.

9. The computer-readable storage medium of claim 8, wherein the plurality of alignment plates are spaced using one or more multi-piece spacers.

10. The computer-readable storage medium of claim 9, wherein each of the one or more multi-piece spacers is assembled from at least two parts.

11. The computer-readable storage medium of claim 8, wherein the plurality of alignment plates includes at least an upper alignment plate and a lower alignment plate.

12. The computer-readable storage medium of claim 11, wherein the plurality of alignment plates further includes:
a floating alignment plate, provided between the upper and lower alignment plates, to control a bending or flexing of the probe wires.

13. The computer-readable storage medium of claim 12, wherein the floating alignment plate enables the probe wires to bend or flex without contacting one another.

14. A probe head comprising:
a plurality of spaceable alignment plates, wherein each of the plurality of alignment plates includes a set of holes;
a set of probe wires inserted through the set of holes, respectively, in each of the plurality of spaceable alignment plates; and
one or more multi-piece spacers provided between the plurality of spaceable alignment plates to enable the set of probe wires to bend or flex when making contact with a device under test.

15. The probe head of claim 14, wherein each of the one or more multi-piece spacers is assembled from at least two parts.

16. The probe head of claim 14, wherein the plurality of spaceable alignment plates includes at least an upper alignment plate and a lower alignment plate.

17. The probe head of claim 16, wherein the plurality of spaceable alignment plates further includes:
a floating alignment plate, provided between the upper and lower alignment plates, to control a bending or flexing of the probe wires.

18. The probe head of claim 17, wherein the floating alignment plate enables the probe wires to bend or flex without contacting one another.

19. A probe assembly tooling comprising:
means for stacking a plurality of alignment plates so that each of the plurality of alignment plates is adjacent to at least one other alignment plate and a set of holes in each of the plurality of alignment plates is aligned with a corresponding set of holes in each of the remaining alignment plates;
means for inserting a set of probe wires through the set of holes, respectively, in each of the plurality of alignment plates; and
means for spacing the plurality of alignment plates, after the set of probe wires are inserted, so that none of the plurality of alignment plates is adjacent to another alignment plate.
